(19) United States
(12) Patent Application Publication
(10) Pub. No.: US 2025/0081730 A1
(43) Pub. Date: Mar. 6, 2025

(54) Display with Vertically Stacked Components

(71) Applicant: Apple Inc., Cupertino, CA (US)

(72) Inventors: Andrew Lin, San Jose, CA (US); Alper Ozgurluk, Sunnyvale, CA (US); Chao Liang Chien, Hsinchu (TW); Cheuk Chi Lo, Belmont, CA (US); Chia-Yu Chen, Zhubei (TW); Chien-Chung Wang, Tainan (TW); Chih Pang Chang, Hsinchu (TW); Chih-Hung Yu, Taoyuan (TW); Chih-Wei Chang, Taipei (TW); Chin Wei Hsu, Hsinchu (TW); ChinWei Hu, Hsinchu (TW); Chun-Kai Tzeng, Hsinchu (TW); Chun-Ming Tang, Saratoga, CA (US); Chun-Yao Huang, San Jose, CA (US); Hung-Che Ting, Taipei (TW); Jung Yen Huang, Taoyuan (TW); Lungpao Hsin, Kaohsiung (TW); Shih Chang Chang, Cupertino, CA (US); Tien-Pei Chou, Hsinchu (TW); Wen Sheng Lo, Taoyuan (TW); Yu-Wen Liu, Zhubei (TW); Yung Da Lai, Hsinchu (TW)

(21) Appl. No.: 18/755,498

(22) Filed: Jun. 26, 2024

Related U.S. Application Data
(60) Provisional application No. 63/580,628, filed on Sep. 5, 2023.

(51) Int. Cl. H10K 59/121; H10K 59/131

(52) U.S. Cl. CPC H10K 59/1213; H10K 59/1216; H10K 59/131

(57) ABSTRACT

A display may include an array of pixels such as light-emitting diode pixels. The pixels may include multiple circuitry decks that each include one or more circuit components such as transistors, capacitors, and/or resistors. The circuitry decks may be vertically stacked. Each circuitry deck may include a planarization layer formed from a siloxane material that conforms to underlying components and provides a planar upper surface. In this way, circuitry components may be vertically stacked to mitigate the size of each pixel footprint. The circuitry components may include capacitors that include both a high-k dielectric layer and a low-k dielectric layer. The display pixel may include a via with a width of less than 1 micron.

This application claims the benefit of U.S. provisional patent application No. 63/580,628 filed Sep. 5, 2023, which is hereby incorporated by reference herein in its entirety.

### BACKGROUND

Electronic devices often include displays. For example, cellular telephones and portable computers include displays for presenting information to users. An electronic device may have an organic light-emitting diode display based on organic-light-emitting diode pixels or a liquid crystal display based on liquid crystal pixels.

Display pixels include circuit components such as capacitors and transistors. However, these components may have a greater footprint than desired, limiting the maximum pixel density of the display.

It is within this context that the embodiments herein arise.

### SUMMARY

A display pixel may be configured to emit light in a first direction. The display pixel may include a substrate, a first transistor that is formed on the substrate, a first planarization layer that overlaps the first transistor in the first direction, a component that overlaps the first transistor in the first direction and that comprises a capacitor or a transistor, a second planarization layer that overlaps the component in the first direction, and an anode that overlaps the first transistor and the component in the first direction.

A display pixel may include a first power supply terminal, a second power supply terminal, a light-emitting diode, a drive transistor, a switching transistor that is connected to a gate of the drive transistor, a substrate, a first deck on the substrate that includes the switching transistor and a first planarization layer that overlaps the switching transistor, and a second deck on the first deck that includes the drive transistor and a second planarization layer that overlaps the drive transistor. The drive transistor and the light-emitting diode may be connected in series between the first and second power supply terminals.

A display may include an array of display pixels with a pixel density of greater than 1000 pixels per inch. A display pixel in the array of display pixels may include a light-emitting diode configured to emit light vertically, a drive transistor with a first gate that is vertically overlapped by the light-emitting diode, and an additional transistor with a second gate that is vertically overlapped by the light-emitting diode and the first gate.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3A is a circuit diagram of an illustrative display pixel with six transistors and one capacitor in accordance with some embodiments.

FIG. 3B is a circuit diagram of an illustrative display pixel with four transistors and two capacitors in accordance with some embodiments.

FIG. 4 is a side view of an illustrative display pixel with a first deck having a transistor and a second deck having a capacitor in accordance with some embodiments.

FIG. 5 is a side view of an illustrative display pixel with a first deck having a transistor and a second deck having a capacitor and a transistor in accordance with some embodiments.

FIG. 6 is a side view of an illustrative display pixel with a first deck having two transistors, a second deck having two transistors, and a third deck having at least one capacitor in accordance with some embodiments.

FIG. 7A is a side view of partially overlapping vias in accordance with some embodiments.

FIG. 7B is a side view of nested vias in accordance with some embodiments.

FIG. 8 is a side view of an illustrative capacitor with two electrodes and one high-k dielectric layer sandwiched between two low-k dielectric layers between the two electrodes in accordance with some embodiments.

FIG. 9 is a side view of an illustrative capacitor with three planar electrodes and one high-k dielectric layer sandwiched between two low-k dielectric layers between each adjacent pair of electrodes in accordance with some embodiments.

FIG. 10 is a side view of an illustrative capacitor with three non-planar electrodes and one high-k dielectric layer sandwiched between two low-k dielectric layers between each adjacent pair of electrodes in accordance with some embodiments.

FIG. 11 is a side view of an illustrative capacitor with an electrode that has adjacent portions at a non-orthogonal, non-parallel angle in accordance with some embodiments.

### DETAILED DESCRIPTION

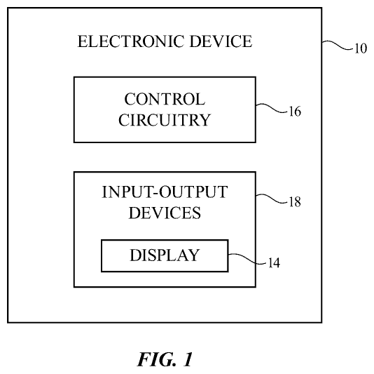

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, an augmented reality (AR) headset and/or virtual reality (VR) headset, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment.

As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 18 may be used to allow data to be supplied to device 10 and to allow data to be provided from device 10 to external devices. Input-output devices 18 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 18 and may receive status information and other output from device 10 using the output resources of input-output devices 18.

Input-output devices 18 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Control circuitry 16 may be used to run software on device 10 such as operating system code and applications. During operation of device 10, the software running on control circuitry 16 may display images on display 14.

Display 14 may be an organic light-emitting diode display, a display formed from an array of discrete light-emitting diodes each formed from a crystalline semiconductor die, or any other suitable type of display. Configurations in which the pixels of display 14 include light-emitting diodes are sometimes described herein as an example. This is, however, merely illustrative. Any suitable type of display may be used for device 10, if desired (e.g., a liquid crystal display).

In some cases, electronic device 10 may be a wristwatch device. Display 14 of the wristwatch device may be positioned in a housing. A wristwatch strap may be coupled to the housing.

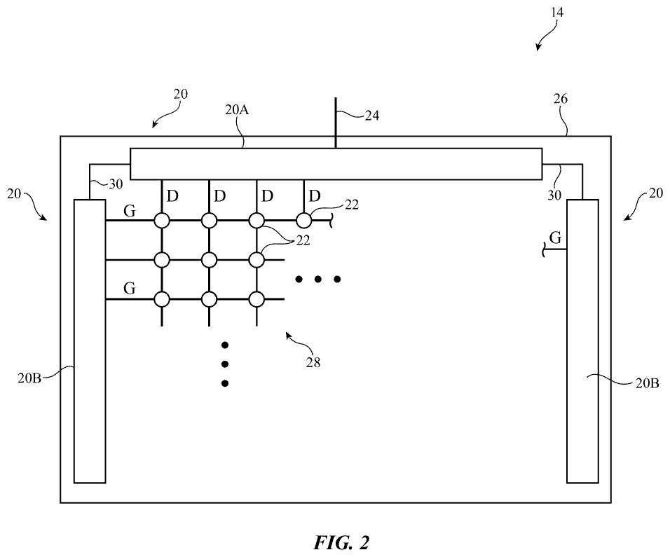

FIG. 2 is a diagram of an illustrative display. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, composite films that include polymer and inorganic materials, metallic foils, etc.

Display 14 may have an array of pixels 22 for displaying images for a user such as pixel array 28. Pixels 22 in array 28 may be arranged in rows and columns. The edges of array 28 (sometimes referred to as active area 28) may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels. If desired, a backlight unit may provide backlight illumination for display 14.

Display driver circuitry 20 may be used to control the operation of pixels 28. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 in an inactive area of the display as shown in FIG. 2. Gate driver circuitry 20B may include gate drivers and emission drivers.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, the control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply

corresponding image data to data lines D (e.g., vertical signal lines) while issuing control signals to supporting display driver circuitry such as gate driver circuitry 20B over signal paths 30. With the illustrative arrangement of FIG. 2, data lines D run vertically through display 14 and are associated with respective columns of pixels 22. During compensation operations, column driver circuitry 20 may use paths such as data lines D to supply a reference voltage.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally through display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.). The number of horizontal signal lines in each row may be determined by the number of transistors in the display pixels 22 that are being controlled independently by the horizontal signal lines. Display pixels of different configurations may be operated by different numbers of control lines, data lines, power supply lines, etc.

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., thin-film circuitry on substrate 26) that responds to the control and data signals from display driver circuitry 20.

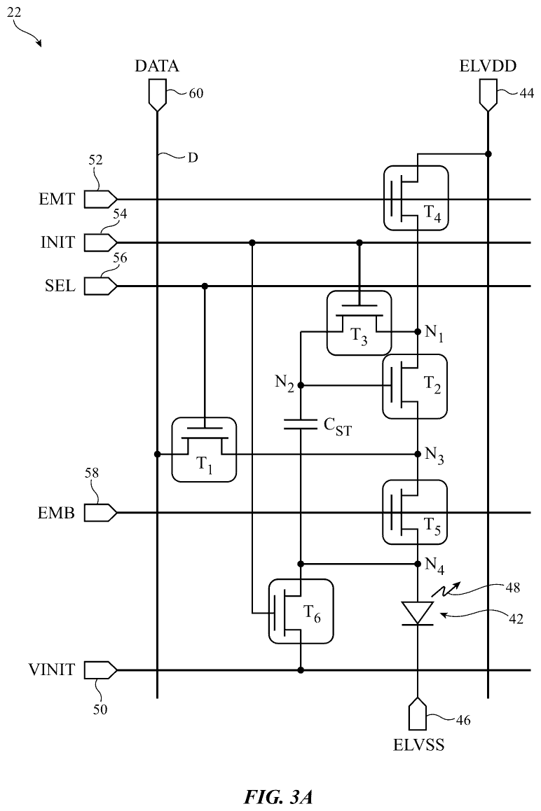

FIG. 3 is a circuit diagram of an illustrative organic light-emitting diode display pixel 22 in display 14. As shown in FIG. 3A, display pixel 22 may include a storage capacitor Cst, a drive transistor T₂, switching transistors such as transistors T₁, T₃, and T₆, and emission transistors such as T₄ and T₅.

In general, each transistor in pixel 22 may be formed using semiconducting oxide or silicon. A semiconducting oxide transistor may have a channel formed from semiconducting oxide such as indium gallium zinc oxide (IGZO). A silicon transistor may have a polysilicon channel deposited using a low temperature process. The polysilicon deposited using the low temperature process may sometimes be referred to as low-temperature polysilicon (LTPS).

In general, the transistors in pixel 22 may include n-type (i.e., n-channel) transistors and/or p-type (i.e., p-channel) transistors. In one illustrative example, each one of transistors T₁, T₂, T₃, T₄, T₅, and T₆ is an n-channel semiconducting oxide transistor. Semiconducting-oxide transistors exhibit relatively lower leakage than silicon transistors, so implementing the transistors of display pixel 22 as semiconducting-oxide transistors may mitigate flicker (e.g., by preventing current from leaking away from the gate terminal of drive transistor T₂).

Transistor T₂ serves as the drive transistor for pixel 22 and has a threshold voltage (Vth) that impacts the emission current of pixel 22. Since the threshold voltage of transistor Tdrive may experience hysteresis, forming the drive transistor as a top-gate semiconducting-oxide transistor may help reduce the hysteresis (e.g., a top-gate IGZO transistor experiences less Vth hysteresis than a silicon transistor).

Display pixel 22 may include an organic light-emitting diode (OLED) 42. A positive power supply voltage ELVDD may be supplied to positive power supply terminal 44, and a ground power supply voltage ELVSS may be supplied to ground power supply terminal 46. Positive power supply voltage ELVDD may be 3 V, 4 V, 5 V, 6 V, 7 V, 2 to 8 V, or any suitable positive power supply voltage level. Ground power supply voltage ELVSS may be 0 V, −1 V, −2V, −3 V, −4 V, −5 V, −6V, −7 V, or any suitable ground or negative power supply voltage level. The state of drive transistor T₂ controls the amount of current flowing from terminal 44 to terminal 46 through diode 42, and therefore the amount of emitted light 48 from display pixel 22.

Terminal 50 may be used to supply an initialization voltage VINIT (e.g., a negative voltage such as −1 V, −2 V, −3 V, −4V, −5 V, −6 V, or other suitable voltage) to assist in turning off diode 42 when diode 42 is not in use. Terminal 50 is therefore sometimes referred to as the initialization line.

Control signals from display driver circuitry such as gate driver circuitry 20B of FIG. 2 are supplied to control terminals such as row control terminals 52, 54, 56, and 58. Row control terminals 52 and 58 may serve as emission control terminals (sometimes referred to as an emission lines or emission control lines). Row control terminals 54 and 56 may serve as first and second scan control terminals (sometimes referred to as scan lines, scan control lines, switching lines, switching control lines, etc.). The row control terminals 52, 54, 56, and 58 may themselves sometimes be referred to as row control lines or gate lines. Alternatively, the row control terminals may be referred to as being coupled to respective row control lines or gate lines.

Emission control signal EMT may be supplied to terminal 52. Emission control signal EMB may be supplied to terminal 58. Scan control signal INIT may be supplied to scan terminal 54. Scan control signal SEL may be supplied to scan terminal 56. A data input terminal such as data signal terminal 60 is coupled to a respective data line D for receiving image data for display pixel 22. Data terminal 60 may also be referred to as the data line.

Control signals EMT, INIT, SEL, and EMB for modulating the n-type semiconducting-oxide transistors T₄, T₃, T₆, T₁, and T₅ may be driven high to turn on those transistors (since n-type transistors are “active-high” devices) and driven low to turn them off. Control signals EMT, INIT, SEL, and EMB, when asserted, may generally be driven to a voltage level that is higher than ELVDD to overdrive the transistor. As an example, if ELVDD is equal to 5 V, signals EMT, INIT, SEL, and EMB might be driven to 12 V when asserted. Control signals EMT, INIT, SEL, and EMB, when deasserted, may generally be driven to a voltage level that is lower than ELVSS to minimize leakage through the transistors. As an example, if ELVSS is equal to −2 V, signals EMT, INIT, SEL, and EMB might be driven to −6 V when deasserted. The disclosed high and low voltage levels for each of these row control signals are merely illustrative and can be adjusted to other suitable voltage levels to support the desired mode of operation.

The terms “source” and “drain” terminals of a transistor can sometimes be used interchangeably and may therefore sometimes be referred to as “source-drain” terminals herein.

In the example of FIG. 3A, transistors T₄, T₂, T₅, and OLED 42 are coupled in series (in that order) between power supply terminals 44 and 46. In particular, first emission control transistor T₄ may have a first source-drain terminal that is coupled to positive power supply terminal 44, a gate terminal that receives emission control signal EMT, and a second source-drain terminal coupled to node N₁.

Drive transistor T₂ may have a first-source drain terminal coupled to node N₁, a gate terminal coupled to node N₂, and a second source-drain terminal coupled to node N₃. Second emission control transistor T₅ may have a first source-drain terminal coupled to node N₃, a gate terminal that receives emission control signal EMB, and a second source-drain terminal coupled to node N₄. Node N₄ is coupled to ground power supply terminal 46 via light-emitting diode 42. Node N₄ is also coupled to transistor T₆ and capacitor Cst. Configured in this way, emission control signals EMT and EMB can be asserted to turn on transistors T₄ and T₅ during an emission phase to allow current to flow through light-emitting diode 42.

Storage capacitor Cst may have a first terminal (e.g., a first plate for the capacitor) that is coupled to node N₂ and a second terminal (e.g., a second plate for the capacitor) that is coupled to node N₄. Image data that is loaded into pixel 22 may be at least partially stored on pixel 22 by using capacitor Cst to hold charge throughout the emission phase.

Transistor T₃ may have a first source-drain terminal coupled to node N₁, a second source-drain terminal coupled to node N₂, and a gate terminal that receives control signal INIT. Signal INIT may be asserted to turn on transistor T₃ and short the gate of drive transistor T₂ (at node N₂) to a source-drain terminal of drive transistor T₂ (at node N₁).

Transistor T₁ (sometimes referred to as data loading transistor T₁) may have a first source-drain terminal coupled to data line D, a gate terminal configured to receive scan control signal SEL, and a second source-drain terminal coupled to node N₃. Configured in this way, signal SEL can be asserted to turn on transistor T₁, which will allow a data voltage from data line D to be loaded onto node N₃.

As shown in FIG. 3A, pixel 22 also includes a transistor T₆ with a first source-drain terminal connected to node N₄, a gate terminal configured to receive scan control signal INIT, and a second source-drain terminal connected to initialization line 50 on which initialization voltage VINIT is provided. Transistors T₃ and T₆ are both controlled by control signal INIT and are therefore controlled in parallel.

The arrangement of pixel 22 in FIG. 3A is merely illustrative. In general, one or more additional transistors may be included (e.g., to support in-pixel threshold voltage compensation, external threshold voltage compensation, and/or other desired operations). The example of using all n-type semiconducting oxide transistors is merely illustrative. If desired, one or more transistors in pixel 22 of FIG. 3A may be formed using p-type silicon transistors. One or more transistors may also optionally be omitted from the pixel of FIG. 3A.

FIG. 3B is a circuit diagram of an illustrative display pixel with four transistors and two capacitors. In this arrangement, emission transistor T₅ from FIG. 3A has been omitted. There is therefore only one emission transistor T₄ that is controlled by row control signal EM.

In FIG. 3B, transistor T₁ has a first source-drain terminal coupled to data line D, a gate terminal that receives control signal SEL, and a second source-drain terminal that is coupled to the gate of drive transistor T₂ at node N₂.

Pixel 22 of FIG. 3B has a first capacitor C₁ and a second capacitor C₂. The first capacitor has a first terminal (sometimes referred to as a first plate) that is coupled to the gate of drive transistor T₂ at node N₂. The first capacitor has a second terminal (sometimes referred to as a second plate) that is coupled to node N₃. The second capacitor has a first terminal (sometimes referred to as a first plate) that is coupled to node N₃ and a second terminal (sometimes referred to as a second plate) that is coupled to initialization voltage terminal 50 or some other fixed reference voltage.

Transistor T₃ has a first source-drain terminal that is coupled to initialization voltage terminal 50, a gate terminal that receives control signal INIT from row control terminal 54, and a second source-drain terminal that is coupled to N₃.

In certain types of devices, it may be desirable for the footprint of each pixel to be small. Small pixels may allow for a high pixel density or PPI (pixels per inch). Transistors and capacitors may contribute to the overall footprint of each display pixel 22. In some cases, the transistors and capacitors may be formed on a single substrate without any lateral overlap. In this case, the overall footprint of the pixel is required to accommodate the footprint of each transistor/capacitor. To shrink the overall footprint of the pixel, one or more components in the pixel may be stacked. For example, one or more transistors and/or capacitors may be stacked vertically, such that the footprint of those components overlap. Stacking components in this manner reduces the total footprint requirements for the pixel.

Herein, display 14 may be referred to as having active devices and passive devices. Active devices may include transistors that include a semiconducting channel (e.g., n-type semiconducting oxide transistors, p-type silicon transistors, etc.). Passive devices may include capacitors (formed from two or more parallel conductive layers) and resistors (formed from a single conductive layer).

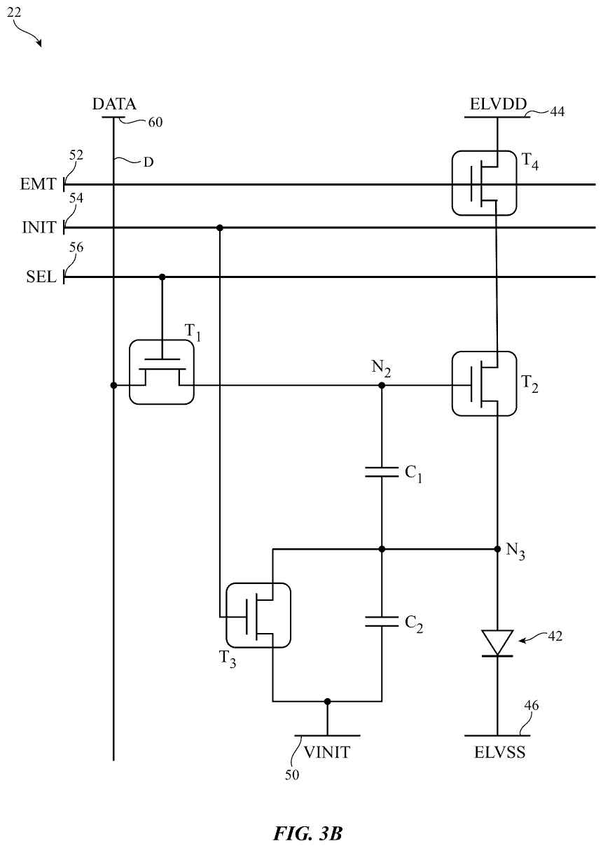

Various combinations of active devices and passive devices may be vertically stacked in display 14. FIG. 4 is a side view of an illustrative pixel 22 with a passive device that is stacked with an active device.

As shown in FIG. 4, pixel 22 may include a substrate 82. Passive component 72 and active component 84 may be vertically stacked on substrate 82. Herein, vertically stacked may mean that the components overlap in a direction parallel to direction 65. Light may be emitted from the pixel (e.g., from light-emitting diode 42) in direction 65 (e.g., towards a viewer). In this example, passive component 72 is a capacitor and active component 84 is a transistor. Substrate 82 may be formed from an insulating material such as polyimide or glass or may be formed from a conductive material (e.g., a material comprising one or more of aluminum, titanium, molybdenum, etc.).

One or more interlayer dielectric layers 74 may be formed over substrate 82. In the example of FIG. 4, a conductive layer 80-2 is formed over substrate 82. An interlayer dielectric layer 74 is interposed between conductive layer 80-2 and substrate 82. A channel region 76 (sometimes referred to as an active region, semiconducting oxide channel, silicon channel, etc.) for transistor 84 is formed over conductive layer 80-2 and separated from conductive layer 80-2 by an interlayer dielectric layer 74. Channel region 76 comprises LTPS when transistor 84 is a silicon transistor and comprises semiconducting oxide when transistor 84 is a semiconducting oxide transistor.

A conductive layer 86 (sometimes referred to as a source-drain terminal) may be electrically connected to active region 76. Conductive layer 86 may form a first source-drain terminal for transistor 84. A conductive layer 88 (sometimes referred to as a source-drain terminal) may be electrically connected to active region 76. Conductive layer 88 may form a second source-drain terminal for transistor 84. Conductive layer 88 may also be electrically connected substrate 82.

A gate 78 for transistor 84 may be formed over active region 76. Gate 78 may be separated from active region 76 by an interlayer dielectric layer 74. More specifically, a gate insulating layer may be interposed between active region 76 and gate 78.

Each plane of components within the display may be referred to as a deck or circuitry deck. Each deck therefore has at least one circuit component (e.g., an active circuit component or a passive circuit component). Each deck may be formed on a planar surface (such that the deck has a planar lower surface) and may have a planarization layer to provide the deck with a planar upper surface. The active circuit components may sometimes be referred to simply as active components. The passive circuit components may sometimes be referred to simply as passive components.

In the example of FIG. 4, a first deck 90-1 includes active component 84 and a second deck 90-2 includes passive component 72.

A planarization layer 70-1 for first deck 90-1 may be formed over and directly contact interlayer dielectric layer(s) 74, conductive layer 86, and conductive layer 88. The planarization layer conforms to the underlying components and has a planar top surface. The planarization layer may be formed from a siloxane material, polyimide polymer material, or any other desired material.

Conductive layer 80-1 may be formed on the upper surface of planarization layer 70-1. One or more interlayer dielectric layers may be formed over conductive layer 80-1. Passive component 72 is formed over conductive layer 80-1. Passive component 72 includes first and second conductive layers 72-1 and 72-2 that are separated by an interlayer dielectric layer 74. The first and second conductive layers 72-1 and 72-2 may form first and second plates for a capacitor, respectively. As shown in FIG. 4, conductive layer 72-1 may be electrically connected to conductive layer 86 through a via (92-1) in planarization layer 70-1.

A planarization layer 70-2 for second deck 90-2 may be formed over and directly contact interlayer dielectric layer(s) 74 and conductive layer 72-1. The planarization layer conforms to the underlying components and has a planar top surface. The planarization layer may be formed from a siloxane material or any other desired material.

Light-emitting diode 42 may be formed over planarization layer 70-2. The light-emitting diode includes an anode 62, organic light-emitting diode (OLED) layers 68, and a cathode 66. OLED layers 68 are interposed between anode 62 and cathode 66. A pixel definition layer 64 that defines an aperture for the pixel may also be included in pixel 22. The example of FIG. 4 where LED 42 is an OLED is merely illustrative. In general, LED 42 may be any desired type of LED (e.g., an inorganic LED or an OLED).

An example has been described where planarization layers 70-1 and 70-2 are formed from a siloxane material (e.g., a material with a Si—O—Si chain). The planarization layers may have a dielectric constant that is between 2.6 and 3.2, greater than 2, less than 3.5, etc. Using a siloxane material for the planarization layers may cause the upper surface to have a variation of less than 0.3 microns in the thickness direction (e.g., parallel to direction 65 in FIG. 4) across the surface of the planarization layer. The siloxane material may also have favorable properties with respect to adhesion and outgassing.

FIG. 4 shows an example where pixel 22 includes a first via 92-1 and a second via 92-2. Conductive layer 72-2 extends through via 92-1 in planarization layer 70-1 to contact conductive layer 86. Anode 62 extends through via 92-2 in planarization layer 70-2 to contact conductive layer 72-1.

Vias 92-1 and 92-2 may be characterized by a width. Via 92-1 has a width 94-1 and via 92-1 has a width 94-2. For the vias, width may refer to the width at the narrowest portion of the via (e.g., at the bottom of the via). Mitigating the width of the vias may reduce the footprint requirements for pixel 22. Each one of widths 94-1 and 94-2 may be less than 1 micron, less than 0.8 microns, less than 0.6 microns, between 0.2 microns and 0.8 microns, etc. To manufacture the vias with widths less than 1 micron (sometimes referred to as sub-micron vias), photoresist patterning may first be used to achieve a via with a width that is greater than one micron. A water-based resolution enhancement treatment (RET) may subsequently be performed. During the water-based resolution enhancement treatment, a water-based polymer material combines with the photoresist to shrink the overall width of the via (e.g., to a width that is less than one micron). This example is merely illustrative and other processes may be used to create sub-micron vias if desired.

Stacking components for pixel 22 as in FIG. 4 may allow for a high pixel density in display 14 (e.g., greater than 600 PPI, greater than 800 PPI, greater than 1000 PPI, etc.).

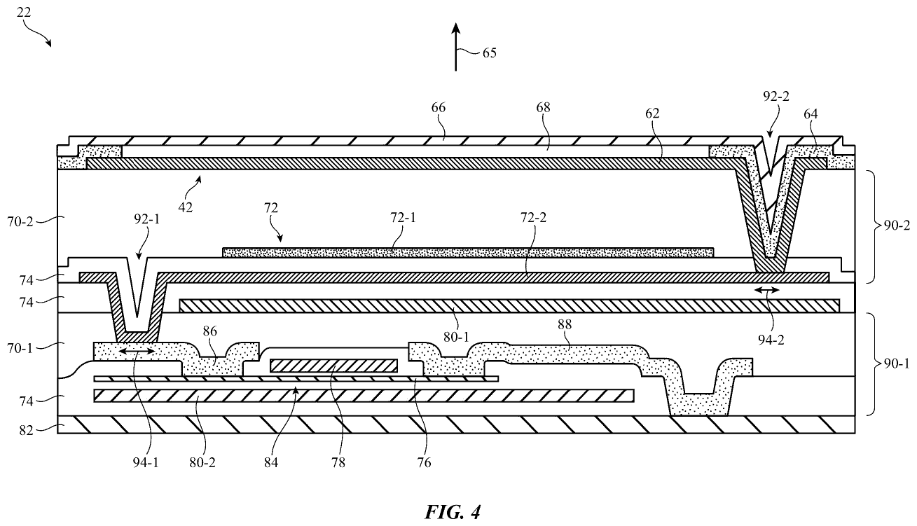

The example in FIG. 4 of a passive component being stacked over an active component is merely illustrative. In another possible example, shown in FIG. 5, the first deck includes an active component and the second deck includes a stacked active component and passive component. Deck 90-1 in FIG. 5 is the same as in FIG. 4 and therefore will not be described again for simplicity.

Deck 90-2 in FIG. 5 includes a conductive layer 80-1 (similar to as in FIG. 4). A transistor 96 (sometimes referred to as active component 96) is formed over conductive layer 80-1. Transistor 96 includes a channel region 98 (sometimes referred to as an active region, channel, etc.). Channel region 98 is separated from conductive layer 80-1 by an interlayer dielectric layer 74.

A conductive layer 102 (sometimes referred to as a source-drain terminal) may be electrically connected to active region 98. Conductive layer 102 may form a source-drain terminal for transistor 96.

A gate 100 for transistor 96 may be formed over active region 98. Gate 100 may be separated from active region 98 by an interlayer dielectric layer 74. More specifically, a gate insulating layer may be interposed between active region 98 and gate 100.

A conductive layer 104 may be formed over transistor 96. Conductive layer 104 may be separated from gate 100 and conductive layer 102 by an interlayer dielectric layer 74. Conductive layer 104 is electrically connected to conductive layer 86 through via 92-1.

Capacitor 72 may be stacked over transistor 96 within deck 90-2. As shown in FIG. 5, capacitor 72 includes a first conductive layer 72-2 and a second conductive layer 72-1. An interlayer dielectric layer 74 is interposed between conductive layers 72-1 and 72-2. An interlayer dielectric layer 74 is interposed between conductive layers 72-2 and 104. Conductive layer 104 may optionally form a third electrode for capacitor 72.

As shown in FIG. 5, conductive layer 72-2 is electrically connected to active region 98. Additionally, anode 62 is electrically connected to conductive layer 72-2 through via 02-2 in planarization layer 70-2.

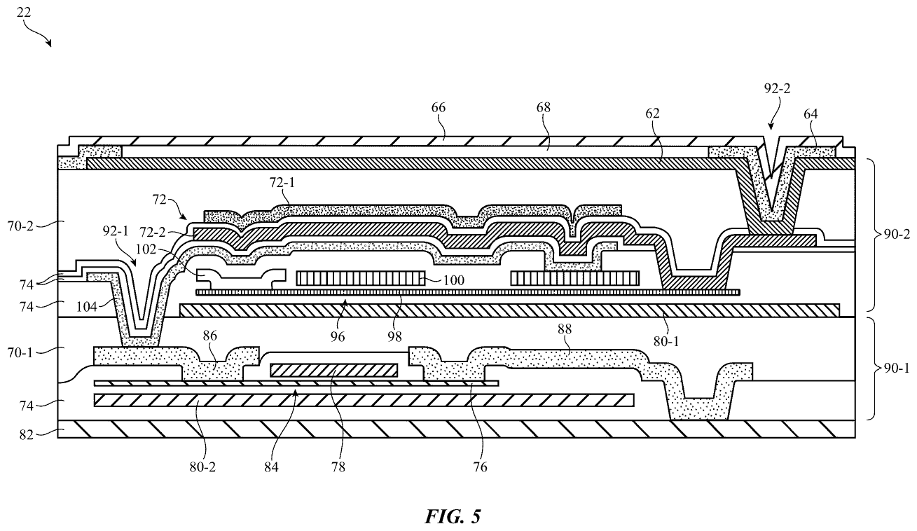

Another example of a pixel with vertically stacked components is shown in FIG. 6. In the example of FIG. 6, the pixel includes three decks (90-1, 90-2, 90-3), each of which includes at least one component. In FIG. 6, deck 90-1 includes transistors 128 and 130, deck 90-2 includes transistors 142 and 144, and deck 90-3 includes capacitor(s) 152. Each one of transistors 128, 130, 142, and 144 may be semiconducting oxide transistors or silicon transistors.

Transistor 128 in deck 90-1 includes an active region 112, gate 114, first source-drain terminal 116, and second source-drain terminal 118. A conductive layer 80-1 may be formed under channel region 112 and may be separated from channel region 112 by an interlayer dielectric layer 74. An interlayer dielectric layer (e.g., a gate insulating layer) may be formed between channel region 112 and gate 114.

Transistor 130 in deck 90-1 includes an active region 120, gate 122, first source-drain terminal 124, and second source-drain terminal 126. A conductive layer 80-2 may be formed under channel region 120 and may be separated from channel region 120 by an interlayer dielectric layer 74. An interlayer dielectric layer (e.g., a gate insulating layer) may be formed between channel region 120 and gate 122.

Planarization layer 70-1 is formed over and conforms to interlayer dielectric layer(s) 74 and source-drain terminals 116, 118, 124, and 126. The upper surface of planarization layer 70-1 serves as a planar substrate for deck 90-2. Planarization layer 70-1 may be formed from siloxane or polyimide, as previously discussed.

Transistor 142 in deck 90-2 includes a channel region 132, gate 134, and source-drain terminal 136. A conductive layer 80-3 may be formed under channel region 132 and may be separated from channel region 132 by an interlayer dielectric layer 74. An interlayer dielectric layer (e.g., a gate insulating layer) may be formed between channel region 132 and gate 134.

Transistor 144 in deck 90-2 includes channel region 132, gate 138, and source-drain terminal 140. A conductive layer 80-4 may be formed under channel region 132 and may be separated from channel region 132 by an interlayer dielectric layer 74. An interlayer dielectric layer (e.g., a gate insulating layer) may be formed between channel region 132 and gate 138.

The example in FIG. 6 of transistors 142 and 144 sharing a channel region is merely illustrative. If desired, transistors 142 and 144 may have discrete respective channel regions.

Planarization layer 70-2 is formed over and conforms to interlayer dielectric layer(s) 74 and source-drain terminals 136 and 140. The upper surface of planarization layer 70-2 serves as a planar substrate for deck 90-3. Planarization layer 70-2 may be formed from siloxane or polyimide, as previously discussed.

Capacitor(s) 152 may include two capacitors. A first capacitor is formed using

conductive layer 146 and conductive layer 148. A second capacitor is formed using conductive layer 148 and conductive layer 150. Interlayer dielectric layers may be interposed between conductive layers 146, 148, and 150. Alternatively, conductive layers 146, 148 and 150 may serve as three electrodes for a single capacitor.

As shown in FIG. 6, conductive layer 146 may be electrically connected to the gate 138 of transistor 144 through a via in planarization layer 70-2. Conductive layer 148 may be electrically connected to channel region 132 through a via in planarization layer 70-2.

Planarization layer 70-3 is formed over and conforms to interlayer dielectric layer(s) 74 and conductive layer 150. The upper surface of planarization layer 70-3 serves as a planar substrate for anode 62. Anode 62 may be electrically connected to conductive layer 148 through a via in planarization layer 70-3. Planarization layer 70-3 may be formed from siloxane or polyimide, as previously discussed.

It is noted that the conductive layers 80 in FIGS. 4-6 may serve as shields for the components they overlap. For example, conductive layer 80-1 serves as a shield for transistor 128, conductive layer 80-2 serves as a shield for transistor 130, etc. Conductive layers 80 may also have a planar upper surface that ensures planarity of overlying components.

In general, the transistors and capacitors shown as examples in FIGS. 4-6 may correspond to any desired transistors and capacitors in display pixel 22 or in display driving circuitry (e.g., data driving circuitry 20A or gate driving circuitry 20B from FIG. 2). In other words, circuitry outside of the light-emitting area of the display may include vertically stacked active and/or passive components in multiple decks (as in FIGS. 4-6). In general, the concept of vertically stacked active and/or passive components may be applied to any desired active and/or passive components in electronic device 10.

Capacitor 72 in FIG. 4 may correspond to Cst from FIG. 3A, C₁ from FIG. 3B, or C₂ form FIG. 3B. Transistor 84 from FIG. 4 may correspond to any one of T₁, T₂, T₃, T₄, T₅, or T₆ from FIG. 3A or any one of T₁, T₂, T₃, or T₄ from FIG. 3B.

As a specific example, transistor 84 in FIG. 4 may correspond to drive transistor T₂ in FIG. 3A and capacitor 72 may correspond to capacitor Cst in FIG. 3A. As another specific example, transistor 84 in FIG. 4 may correspond to drive transistor T₂ in FIG. 3B and capacitor 72 may correspond to capacitor C₁ in FIG. 3B.

Capacitor 72 in FIG. 5 may correspond to Cst from FIG. 3A, C₁ from FIG. 3B, C₂ from FIG. 3B, or C₁ and C₂ from FIG. 3B. Transistor 84 from FIG. 5 may correspond to any one of T₁, T₂, T₃, T₄, T₅, or T₆ from FIG. 3A or any one of T₁, T₂, T₃, or T₄ from FIG. 3B. Transistor 96 from FIG. 5 may correspond to any one of T₁, T₂, T₃, T₄, T₅, or T₆ from FIG. 3A or any one of T₁, T₂, T₃, or T₄ from FIG. 3B.

As a specific example, transistor 96 in FIG. 5 may correspond to drive transistor T₂ in FIG. 3A, transistor 84 in FIG. 5 may correspond to transistor T₆ in FIG. 3A, and capacitor 72 may correspond to capacitor Cst in FIG. 3A. As another specific example, transistor 96 in FIG. 5 may correspond to drive transistor T₂ in FIG. 3B, transistor 84 in FIG. 5 may correspond to transistor T₃ in FIG. 3B, and capacitor 72 may correspond to capacitor C₁ in FIG. 3B.

Capacitor(s) 152 in FIG. 6 may correspond to Cst from FIG. 3A, C₁ from FIG. 3B, C₂ from FIG. 3B, or C₁ and C₂ from FIG. 3B. Transistor 128 from FIG. 6 may correspond to any one of T₁, T₂, T₃, T₄, T₅, or T₆ from FIG. 3A or any one of T₁, T₂, T₃, or T₄ from FIG. 3B.

Transistor 130 from FIG. 6 may correspond to any one of T₁, T₂, T₃, T₄, T₅, or T₆ from FIG. 3A or any one of T₁, T₂, T₃, or T₄ from FIG. 3B. Transistor 142 from FIG. 6 may correspond to any one of T₁, T₂, T₃, T₄, T₅, or T₆ from FIG. 3A or any one of T₁, T₂, T₃, or T₄ from FIG. 3B. Transistor 144 from FIG. 6 may correspond to any one of T₁, T₂, T₃, T₄, T₅, or T₆ from FIG. 3A or any one of T₁, T₂, T₃, or T₄ from FIG. 3B.

As a specific example, transistor 128 in FIG. 6 may correspond to transistor T₆ in FIG. 3A, transistor 130 in FIG. 6 may correspond to transistor T₁ in FIG. 3A, transistor 142 in FIG. 6 may correspond to transistor T₄ in FIG. 3A, transistor 144 in FIG. 6 may correspond to transistor T₂ in FIG. 3A, and capacitor(s) 152 in FIG. 6 may correspond to capacitor Cst in FIG. 3A. As another specific example, transistor 128 in FIG. 6 may correspond to transistor T₃ in FIG. 3B, transistor 130 in FIG. 6 may correspond to transistor T₁ in FIG. 3B, transistor 142 in FIG. 6 may correspond to transistor T₄ in FIG. 3B, transistor 144 in FIG. 6 may correspond to transistor T₂ in FIG. 3B, and capacitor(s) 152 in FIG. 6 may correspond to capacitors C₁ and C₂ in FIG. 3B.

These examples are merely illustrative. In general, any desired number of components may be vertically stacked in multiple decks. The active components may include top-gate transistors, bottom-gate transistors, and/or dual-gate transistors. Each deck may include any desired number of active and/or passive components.

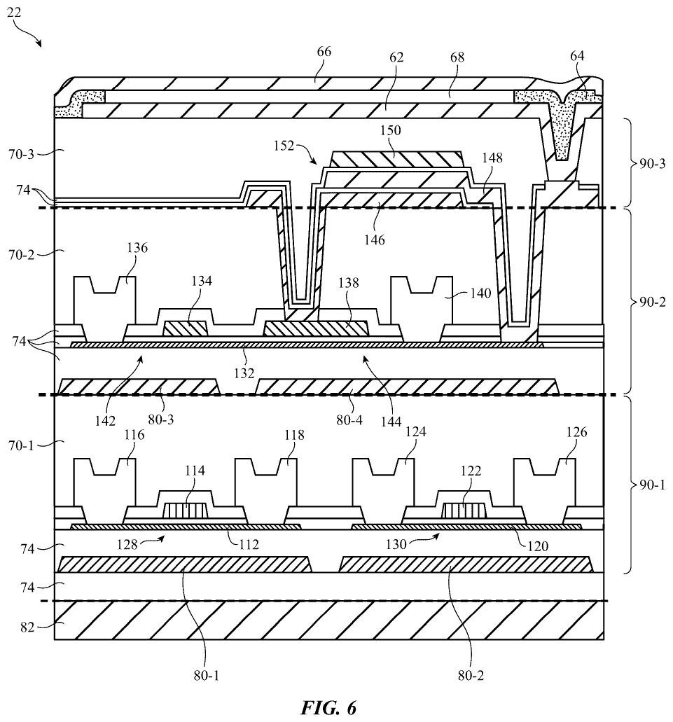

As is shown in FIGS. 4-6, display pixels 22 may include one or more vias to electrically connect components on different decks. To reduce the footprint required for vias, vias may be partially overlapping (as in FIG. 7A) or fully overlapping (as in FIG. 7B). As shown in the partially overlapping vias of FIG. 7A, via 202-2 may accommodate a conductive layer 204-2 and via 202-1 may accommodate a conductive layer 204-1. With the partially overlapping vias of FIG. 7A, conductive layer 204-2 for via 202-2 overlaps an edge surface 206 of conductive layer 204-1 in via 202-1. Accordingly conductive layer 204-2 has a portion that directly contacts an upper surface of conductive layer 204-1, a portion that directly contacts the edge surface 206 of conductive layer 204-1, and a portion that directly contacts an underlying insulating layer 208 (e.g., an interlayer dielectric layer or other insulating substrate). In another possible arrangement, shown in FIG. 7B, conductive layer 204-2 extends into via 202-1 such that the center of via 202-1 is completely overlapped by conductive layer 204-2. Via 202-2 may be referred to as being nested within via 202-1. In this example, via 202-2 has a smaller width than via 202-1 in order to be nested within via 202-1.

Using vias of the type shown in FIGS. 7A and 7B may reduce the footprint requirements for display pixel 22. For example, FIGS. 4 and 5 show a via 92-1 that contacts source-drain terminal 86. Source-drain terminal 86 has a via to electrically connect to active region 76. These two vias may be formed as partially overlapping vias (as in FIG. 7A) or fully overlapping vias (as in FIG. 7B) to reduce the overall footprint of the vias.

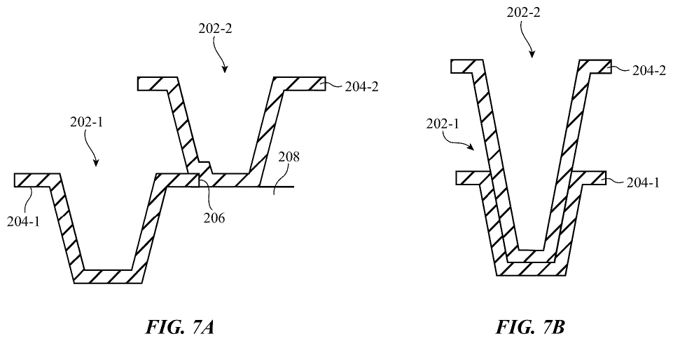

It may be desirable for a capacitor in pixel 22 to have a high capacitance density and low leakage. Generally, including a thin dielectric layer may improve the storage capacity (and therefore capacitance density) of the capacitor. However, a thin dielectric layer may also cause higher leakage from the capacitor. To achieve a high capacitance density while maintain low leakage, alternating layers of high dielectric constant material (sometimes referred to as high-k material) and low dielectric constant material (sometimes referred to as low-k material) may be formed between capacitor electrodes. FIGS. 8-11 show capacitors of this type.

FIG. 8 is a side view of an illustrative capacitor 210. Capacitor 210 includes first and second conductive electrodes 212-1 and 212-2 (sometimes referred to as plates 212-1 and 212-2). Multiple dielectric layers are interposed between electrodes 212-1 and 212-2. The multiple dielectric layers include one or more high-k dielectric layers 216 and one or more low-k dielectric layers 214. In the arrangement of FIG. 8, one high-k dielectric layer 216 is interposed between low-k dielectric layers 214-1 and 214-2.

The low-k dielectric layers 214 may have a dielectric constant that is less than 10, less than 8, less than 6, less than 4, less than 2, greater than 1.5, between 1.5 and 10, etc. High-k dielectric layer 216 may have a dielectric constant that is greater than 10, greater than 12, greater than 15, greater than 20, etc.

Each electrode in capacitor 210 may be formed from a metal or an alloy of two or more metals (e.g., titanium, titanium nitride, copper, aluminum, an aluminum alloy, silver, tungsten, etc.). The high-k dielectric layers in capacitor 210 may be formed from aluminum oxide, hafnium oxide, titanium oxide, or another desired material. The low-k dielectric materials in capacitor 210 may be formed from silicon nitride, silicon dioxide, etc.

Each low-k dielectric layer in a single capacitor may be formed from the same material or different low-k dielectric layers in a single capacitor may be formed from different materials. Each high-k dielectric layer in a single capacitor may be formed from the same material or different high-k dielectric layers in a single capacitor may be formed from different materials.

Including both high-k and low-k dielectric layers in the capacitor (as in FIG. 8) between the capacitor electrodes may achieve high capacitance density while maintaining low leakage.

The example in FIG. 8 of two low-k dielectric layers and one high-k dielectric layer sandwiched between the capacitor electrodes is merely illustrative. In general, two or more alternating low-k and high-k dielectric layers may be positioned between the capacitor electrodes (e.g., two dielectric layers, three dielectric layers as in FIG. 8, four dielectric layers, five dielectric layers, more than five dielectric layers, etc.).

In FIG. 8, upper electrode 212-2 has an upper portion that extends in a first direction and first and second edge portions that extend in a second direction that is orthogonal to the first direction. In this way, the upper electrode 212-2 encloses the lower electrode 212-1. This example is merely illustrative. If desired, the upper electrode 212-2 may simply be formed as a patch on dielectric layer 214-2, as shown by dashed lines 218.

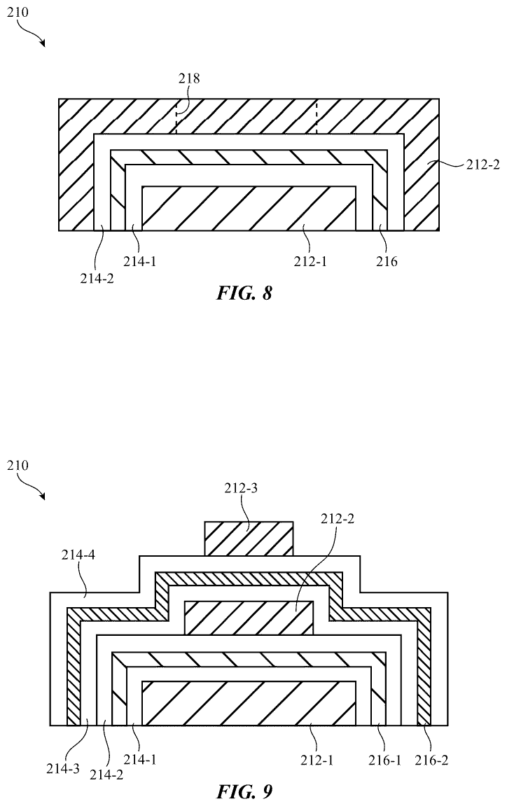

FIG. 8 shows an example with two capacitor electrodes. If desired, capacitor 210 may include three capacitor electrodes. FIG. 9 is an example of this type. A high-k dielectric layer 216-1 sandwiched between low-k dielectric layers 214-1 and 214-2 is interposed between electrodes 212-1 and 212-2. A high-k dielectric layer 216-2 sandwiched between low-k dielectric layers 214-3 and 214-4 is interposed between electrodes 212-2 and 212-3. The additional electrode in FIG. 9 relative to FIG. 8 may further increase the capacitance density of capacitor 210. Alternatively, a structure of the type shown in FIG. 9 may be used to form two capacitors.

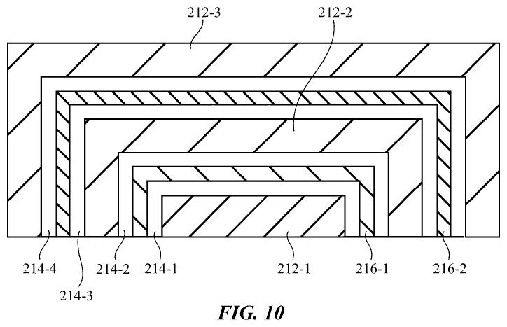

In the example of FIG. 9, each electrode is formed as a patch on a respective dielectric layer. This example is merely illustrative. If desired, each electrode may enclose the underlying electrode(s) as shown in FIG. 10. In FIG. 10, middle electrode 212-2 has an upper portion that extends in a first direction and first and second edge portions that extend in a second direction that is orthogonal to the first direction. In this way, the middle electrode 212-2 encloses the lower electrode 212-1. In FIG. 10, upper electrode 212-3 has an upper portion that extends in the first direction and first and second edge portions that extend in the second direction that is orthogonal to the first direction. In this way, the upper electrode 212-3 encloses electrodes 212-1 and 212-2.

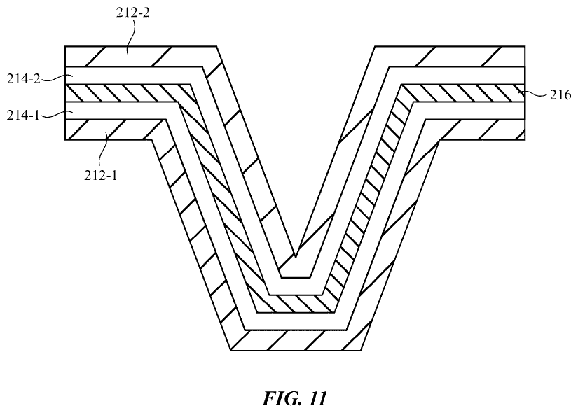

It is further noted that the capacitor may have any desired geometrical shape. As shown in FIG. 11, capacitor electrodes 212-1 and 212-2 may be formed as a via (with both electrodes extending downwards through an opening in a substrate). Electrode 212-1 has adjacent portions at a non-orthogonal, non-parallel angle relative to one another. Electrode 212-2 has adjacent portions at a non-orthogonal, non-parallel angle relative to one another. Using non-planar structures for one or more of the capacitor electrodes in this manner may increase the flexibility in the placement of the capacitor structures in display 14.

To form the capacitor, a plasma process may be used to enhance adhesion between the high-k dielectric layer(s) and overlying low-k dielectric layers. The plasma process may be applied to the high-k dielectric layer(s) before forming the subsequent low-k dielectric layers.

Any of the capacitor structures described in connection with FIGS. 8-11 may be used as the capacitors shown and discussed in connection with FIGS. 3-7.

The foregoing is merely illustrative and various modifications can be made by those skilled in the art without departing from the scope and spirit of the described embodiments. The foregoing embodiments may be implemented individually or in any combination.

What is claimed is:

1. A display pixel configured to emit light in a first direction, the display pixel comprising:
a substrate;
a first transistor that is formed on the substrate;
a first planarization layer that overlaps the first transistor in the first direction;
a component that overlaps the first transistor in the first direction, wherein the component comprises a component selected from the group consisting of: a capacitor and a transistor;
a second planarization layer that overlaps the component in the first direction; and
an anode that overlaps the first transistor and the component in the first direction.

2. The display pixel defined in claim 1, wherein the component is the capacitor.

3. The display pixel defined in claim 2, wherein the capacitor comprises first and second electrodes.

4. The display pixel defined in claim 3, wherein the capacitor comprises first and second dielectric layers between the first and second electrodes, wherein the first dielectric layer has a greater dielectric constant than the second dielectric layer.

5. The display pixel defined in claim 4, wherein the first dielectric layer has a first dielectric constant that is greater than 10 and wherein the second dielectric layer has a second dielectric constant that is between 1.5 and 10.

6. The display pixel defined in claim 4, wherein the capacitor further comprises a third dielectric layer between the first and second electrodes, wherein the second and third dielectric layers are formed from a same material, and wherein the first dielectric layer is interposed between the second and third dielectric layers.

7. The display pixel defined in claim 4, wherein the first dielectric layer comprises a material selected from the group consisting of: aluminum oxide, hafnium oxide, titanium oxide.

8. The display pixel defined in claim 3, wherein the capacitor further comprises a third electrode.

9. The display pixel defined in claim 1, wherein the component is the transistor and wherein the transistor is a second transistor.

10. The display pixel defined in claim 9, wherein the first and second transistors comprise respective first and second channel regions formed from semiconducting oxide.

11. The display pixel defined in claim 9, further comprising:
a capacitor that overlaps the second transistor in the first direction, wherein the capacitor is interposed between the second transistor and the second planarization layer.

12. The display pixel defined in claim 9, further comprising:
a capacitor that overlaps the second transistor in the first direction, wherein the second planarization layer is interposed between the capacitor and the second transistor.

13. The display pixel defined in claim 12, further comprising:
a third planarization layer that overlaps the capacitor in the first direction, wherein the third planarization layer is interposed between the anode and the capacitor.

14. The display pixel defined in claim 1, further comprising:
a conductive via that extends through the first planarization layer, wherein the conductive via has a width that is less than 1 micron.

15. The display pixel defined in claim 1, wherein the first and second planarization layers comprise a siloxane material.

16. The display pixel defined in claim 1, further comprising:
a light-emitting diode that comprises the anode.

17. A display pixel comprising:
a first power supply terminal;
a second power supply terminal;
a light-emitting diode;
a drive transistor, wherein the drive transistor and the light-emitting diode are connected in series between the first and second power supply terminals;
a switching transistor that is connected to a gate of the drive transistor;
a substrate;
a first deck on the substrate that includes the switching transistor and a first planarization layer that overlaps the switching transistor; and
a second deck on the first deck that includes the drive transistor and a second planarization layer that overlaps the drive transistor.

18. The display pixel defined in claim 17, further comprising:
a capacitor that is connected to the gate of the drive transistor; and
a third deck on the second deck that includes the capacitor and a third planarization layer that overlaps the capacitor.

19. The display pixel defined in claim 18, further comprising:
an anode for the light-emitting diode on the third planarization layer.

20. A display comprising:
an array of display pixels with a pixel density of greater than 1000 pixels per inch, wherein a display pixel in the array of display pixels comprises:
a light-emitting diode configured to emit light vertically;
a drive transistor with a first gate that is vertically overlapped by the light-emitting diode; and
an additional transistor with a second gate that is vertically overlapped by the light-emitting diode and the first gate.
